(19) United States
(12) Patent Application Publication
(10) Pub. No.: US 2009/0176124 A1
(43) Pub. Date: Jul. 9, 2009

(54) Bonding pad structure and semiconductor device including the bonding pad structure

(75) Inventors: Jong-Won Hong, Gyeonggi-do (KR); Min-Keun Kwak, Chungcheongnam-do (KR); Geum-Jung Seong, Seoul (KR); Jong-Myeong Lee, Gyeonggi-do (KR); Gil-Heyun Choi, Seoul (KR); Hong-Kyu Hwang, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Gyeonggi-do (KR)

(21) Appl. No.: 12/291,069

(22) Filed: Nov. 5, 2008

(30) Foreign Application Priority Data
Jan. 4, 2008 (KR) 10-2008-0001171

(51) Int. Cl. H01L 29/12; B32B 15/01; B32B 15/04

(52) U.S. Cl. 428/620; 428/650; 428/671; 428/457; 428/645; 428/673; 428/678

(57) ABSTRACT

A bonding pad structure for a semiconductor device includes a first lower metal layer beneath a second upper metal layer in a bonding region of the device. The lower metal layer is formed such that the metal of the lower metal layer is absent from the bonding region. As a result, if damage occurs to the structure during procedures such as probing or bonding at the bonding region, the lower metal is not exposed to the environment. Oxidation of the lower metal layer by exposure to the environment is prevented, thus improving reliability of the device.

### RELATED APPLICATION

This application claims priority to Korean Patent Application number 10-2008-0001171, filed in the Korean Intellectual Property Office on Jan. 4, 2008, the entire contents of which are incorporated herein by reference.

### BACKGROUND OF THE INVENTION

1. Field of the Invention

This application relates to semiconductor devices and methods of manufacturing semiconductor devices. In particular, this application relates to a bonding pad structure for a semiconductor device, a semiconductor device including the bonding pad structure and methods of manufacturing the bonding pad structure and the semiconductor device including the bonding pad structure.

2. Discussion of the Related Art

Semiconductor devices typically include bonding pads which are formed of a conductive layer, for example, a metal layer. Bonding pads are commonly used to measure electrical characteristics of the semiconductor devices. When being tested, a probe is brought into contact with the semiconductor device at the bonding pad. Bonding pads are also used to make electrical contact with bonding wires or bumps when the semiconductor devices are mounted in a package.

FIG. 1 is a schematic cross-sectional view of a conventional bonding pad structure 10 in a semiconductor device. The bonding pad structure 10 includes a first metal layer 12 formed in a first inter-metal dielectric (IMD) layer 16. A second metal layer 14 is formed over the first metal layer 12 in a second IMD layer 18. A protective insulating passivation layer 24 is formed over the second metal layer 14 and the second IMD layer 18. The passivation layer 24 can include two layers, which can be a silicon oxide layer 20 beneath a silicon nitride layer 22. The passivation layer 24 is covered by a photo-sensitive polyimide layer 26. The structure 10 includes an open wire ball region 28 where probes contact the semiconductor device during testing and also where wires are bonded to the device or bumps are formed during the packaging process.

Conventionally, both the first metal layer 12 and the second metal layer 14 have been made of aluminum (Al). However, with the increasing demand for high performance and high integration of devices, bonding pad structures have begun to be made with the lower metal layer 12 being formed of copper (Cu) instead of aluminum.

When probing or wire bonding are performed on the bonding pad, it is possible that the first and/or the second metal layers will be damaged. This can result in the first and/or second metal layer being exposed to the atmosphere. Where the lower metal layer 12 is formed of copper, the copper is very easily oxidized when exposed to the atmosphere. This oxidation of the copper lower metal layer 12 degrades the device or renders the device inoperative.

### SUMMARY OF THE INVENTION

According to the invention, a bonding pad structure for a semiconductor device, a semiconductor device including the bonding pad structure, and methods of manufacturing the structure and device are provided in which the oxidation of a copper lower metal layer of the bonding pad structure is eliminated. In the structure of the invention, no copper of the lower metal layer is present in the wire ball region. As a result, if bonding or probing are performed at the bonding pad structure, oxidation of copper of the lower metal layer of the structure cannot occur, even if damage is caused to the structure by the bonding or the probing. This results in more reliable semiconductor devices.

According to a first aspect, the present invention is directed to a semiconductor device. The device includes a bonding region at which bonding can be performed and a bonding pad structure in the bonding region and extending beyond the bonding region. The bonding pad structure includes a first metal layer and a second metal layer over the first metal layer. In the first metal layer, metal is absent from the bonding region.

The first metal layer can comprise copper or aluminum. A barrier metal layer can be interposed between the first metal layer and the second metal layer. The barrier metal layer can be comprised of at least one of Ta, TaN, TiN and WN.

In one embodiment, the second metal layer comprises aluminum.

In one embodiment, the second metal layer comprises copper. A plating layer may be formed over the second metal layer. The plating layer may comprise at least one of nickel, lead and gold.

In one embodiment, the first metal layer comprises a continuous conductive region electrically coupled to the second metal layer.

In one embodiment, the first metal layer comprises a plurality of conductive pins electrically coupled to the second metal layer.

In one embodiment, the second metal layer comprises a contact plug region electrically coupled to the first metal layer. The contact plug region can include a plurality of conductive plugs in contact with the first metal layer. Alternatively, the contact plug region can include a continuous conductive region electrically coupled to the first metal layer.

In one embodiment, the bonding pad structure further comprises a protection layer under the first metal layer.

According to another aspect, the present invention is directed to a method of making a semiconductor device. According to the method, a substrate is provided, and a bonding region, at which bonding can be performed, is formed in the substrate. A bonding pad structure is formed in the bonding region and extending beyond the bonding region. Formation of the bonding pad structure includes forming a first metal layer and forming a second metal layer over the first metal layer. The first metal layer is formed such that metal of the first metal layer is absent from the bonding region.

The first metal layer can be formed of copper or aluminum. A barrier metal layer can be formed between the first metal layer and the second metal layer. The barrier metal layer can include at least one of Ta, TaN, TiN and WN.

In one embodiment, the second metal layer is formed of aluminum.

In one embodiment, the second metal layer is formed of copper. A plating layer may be formed over the second metal layer. The plating layer may comprise at least one of nickel, lead and gold.

In one embodiment, the first metal layer is formed to have a continuous conductive region electrically coupled to the second metal layer.

In one embodiment, the first metal layer is formed to have a plurality of conductive pins electrically coupled to the second metal layer.

In one embodiment, the second metal layer is formed to have a contact plug region electrically coupled to the first metal layer. The contact plug region can include a plurality of conductive plugs electrically coupled to the first metal layer. Alternatively, the contact plug region includes a continuous conductive region electrically coupled to the first metal layer.

In one embodiment, the method further includes forming a protection layer under the first metal layer.

According to another aspect, the present invention is directed to a bonding pad structure, which includes a first metal layer and a second metal layer over the first metal layer. In the first metal layer, metal of the first metal layer is absent from the bonding region.

The first metal layer can comprise copper or aluminum. A barrier metal layer can be interposed between the first metal layer and the second metal layer. The barrier metal layer can include at least one of Ta, TaN, TiN and WN.

In one embodiment, the second metal layer comprises aluminum.

In one embodiment, the second metal layer comprises copper. A plating layer may be formed over the second metal layer. The plating layer may comprise at least one of nickel, lead and gold.

In one embodiment, the first metal layer comprises a continuous conductive region electrically coupled to the second metal layer.

In one embodiment, the first metal layer comprises a plurality of conductive pins electrically coupled to the second metal layer.

In one embodiment, the second metal layer comprises a contact plug region electrically coupled to the first metal layer. The contact plug region can include a plurality of conductive plugs electrically coupled to the first metal layer. Alternatively, the contact plug region can include a continuous conductive region electrically coupled to the first metal layer.

In one embodiment, the structure further includes a protection layer under the first metal layer.

According to another aspect, the present invention is directed to a method of making a bonding pad structure. According to the method, a first metal layer is formed, and a second metal layer is formed over the first metal layer. The first metal layer is formed such that, in the first metal layer, metal is absent from the bonding region.

The first metal layer can be formed of copper or aluminum. A barrier metal layer can be formed between the first metal layer and the second metal layer. The barrier metal layer can include at least one of Ta, TaN, TiN and WN.

In one embodiment, the second metal layer is formed of aluminum.

In one embodiment, the second metal layer is formed of copper. A plating layer may be formed over the second metal layer. The plating layer may comprise at least one of nickel, lead and gold.

In one embodiment, the first metal layer is formed to have a continuous conductive region electrically coupled to the second metal layer.

In one embodiment, the first metal layer is formed to have a plurality of conductive pins electrically coupled to the second metal layer.

In one embodiment, the second metal layer is formed to have a contact plug region electrically coupled to the first metal layer. The contact plug region can include a plurality of conductive plugs electrically coupled to the first metal layer. Alternatively, the contact plug region can include a continuous conductive region electrically coupled to the first metal layer.

In one embodiment, the method further comprises forming a protection layer under the first metal layer.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a schematic cross-sectional view of a conventional bonding pad structure in a semiconductor device.

FIG. 2 is a schematic cross-sectional view of a bonding pad structure for a semiconductor device, in accordance with one embodiment of the present invention.

FIG. 3 is a schematic top plan view of the first metal layer or lower pad layer of FIG. 2.

FIG. 4 is a schematic cross-sectional view of the lower pad layer taken along line IV-IV′ of FIG. 3.

FIG. 5 is a schematic top plan view of the second metal layer or upper pad layer in the bonding pad structure of FIG. 2.

FIG. 6 is a schematic cross-sectional view of the upper pad layer taken along line VI-VI′ of FIG. 5.

FIGS. 7 through 12 are schematic cross-sectional views illustrating an embodiment of a process of manufacturing the bonding pad structure of a semiconductor device illustrated in FIG. 2.

FIG. 13 is a schematic cross-sectional view of a bonding pad structure of a semiconductor device in accordance with another embodiment of the invention.

FIG. 14 contains a schematic cross-sectional view of the upper pad layer of the bonding pad structure of FIG. 13.

FIGS. 15 and 16 are schematic cross-sectional views illustrating steps in fabricating the bonding pad structure of FIG. 13.

FIG. 17 is a schematic cross-sectional view of a bonding pad structure of a semiconductor device in accordance with another embodiment of the invention.

FIG. 18 contains a schematic top plan view of the lower pad layer of the bonding pad structure of FIG. 17.

FIG. 19 contains a schematic cross-sectional view of the lower pad layer taken along line XIX-XIX′ of FIG. 18.

FIGS. 20 and 21 are schematic cross-sectional views illustrating steps in fabricating the bonding pad structure of FIG. 17.

FIG. 22 is a schematic cross-sectional view of a bonding pad structure of a semiconductor device in accordance with another embodiment of the invention.

FIG. 23 contains a schematic cross-sectional view of a packaged semiconductor device using the bonding pad structures of the invention.

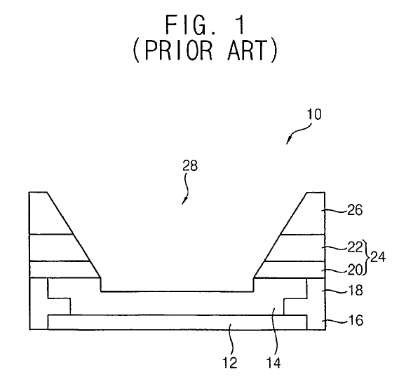

### DETAILED DESCRIPTION OF PREFERRED EMBODIMENTS

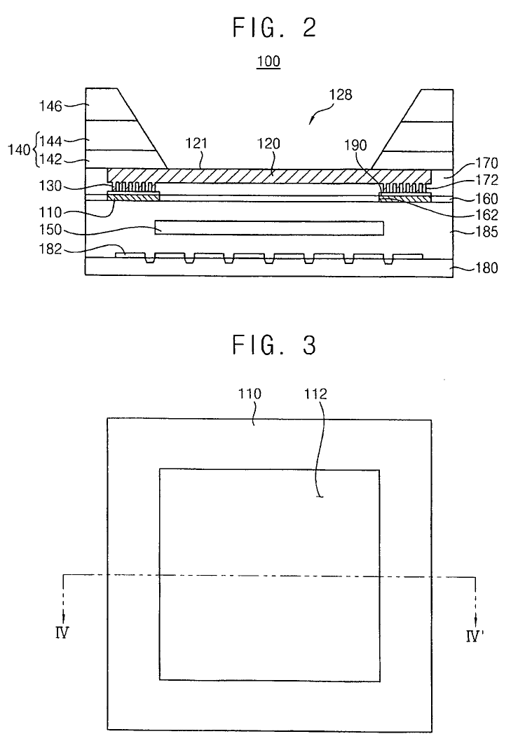

FIG. 2 is a schematic cross-sectional view of a bonding pad structure 100 for a semiconductor device, in accordance with one embodiment of the present invention. The bonding pad structure 100 is formed on a semiconductor substrate 180. Various devices 182 are formed in the substrate 180. An inter-layer dielectric (ILD) layer 185 is formed over the devices 182. An optional probing protect layer 150, which can be formed of an insulating or conducting material, is optionally formed in the ILD layer 185. A first metal layer or lower pad layer 110 is formed over the ILD layer 185 in a first inter-metal dielectric (IMD) layer 160. The first IMD layer 160 includes a trench region 162 in which the metal conductive portion of the lower pad layer 110 is formed. The first metal layer or lower pad layer 110 can be formed of, for example, copper or aluminum. A barrier metal layer 190 may be formed over the lower pad layer 110 to prevent migration of the material of the lower pad layer 110 during subsequent processing steps. The barrier metal layer 190 is particularly useful in the case where the first metal layer 110 is formed of copper. The barrier metal layer 190 can be formed of, for example, Ta, TaN, TiN, WN. It is noted that the barrier metal layer 190 is an optional layer and need not be used.

A second IMD layer 170 is formed over the first IMD layer 160 and the lower pad layer 110. A second metal layer or upper pad layer 120 is formed over the lower pad layer 110 in the second IMD layer 170. The upper pad layer 120 can be formed of, for example, copper or aluminum. The upper pad layer 120 includes a contact plug region 130 protruding from the lower surface of the upper pad layer 120 adjacent to the edge of the upper pad layer 120 in alignment with and electrically coupled to the lower pad layer 110 through the barrier metal layer 190. It is noted that where the barrier metal layer 190 is not present, the contact plug region 130 of the upper pad layer 120 is in contact with the lower pad layer 110. A passivation layer 140, which can include a silicon nitride layer 144 over a silicon oxide layer 142, is formed over the upper pad layer 120. A polyimide layer 146 can be formed over the passivation layer 140.

In the case in which the upper pad layer 120 is made of copper, an additional optional plating layer 121 of nickel (Ni), lead (Pb) and/or gold (Au) plating is formed over the upper pad layer 120. The plating layer 121 can be used to prevent the upper pad layer 120 from oxidizing and for good wire bonding.

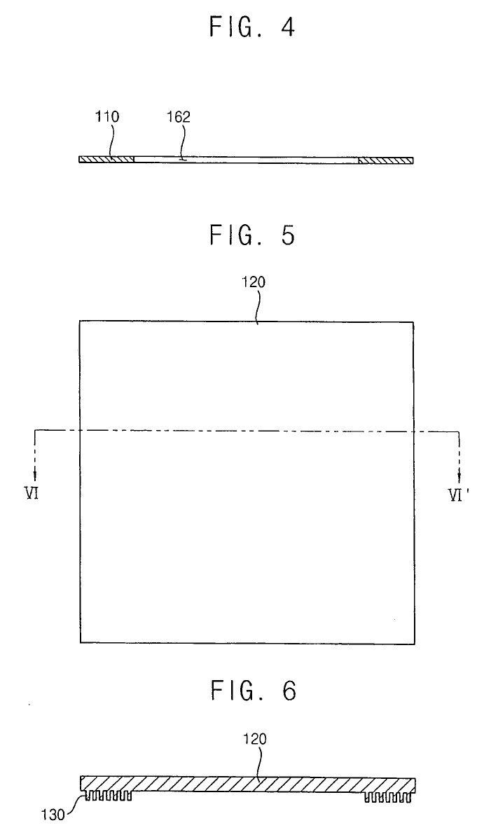

FIG. 3 is a schematic top plan view of the first metal layer or lower pad layer 110 of FIG. 2. FIG. 4 is a schematic cross-sectional view of the lower pad layer 110 taken along lines IV-IV′ of FIG. 3. FIG. 5 is a schematic top plan view of the second metal layer or upper pad layer 120 in the bonding pad structure 100 of FIG. 2. FIG. 6 is a schematic cross-sectional view of the upper pad layer 120 taken along line VI-VI′ of FIG. 5.

Referring to FIGS. 2 through 6, in this embodiment, the lower pad layer 110 is formed in the shape of a conductive region surrounding a rectangular open area 112, defined by the trench portion 162 of the first IMD layer 160. The upper pad layer 120 is also formed as a conductive rectangular pad. The upper pad layer 120 also has a contact plug region 130 which protrudes from its bottom surface. The contact plug region 130 is formed around the perimeter of the upper pad layer 120 such that it is aligned with the conductive portion of the lower pad layer 110. As shown, in this embodiment, the conductive plug 130 includes a plurality of small conductive pins or plugs arranged two-dimensionally in an array. The plurality of conductive pins or plugs in the contact plug 130 are electrically coupled to the conductive portion of the lower pad 110.

As illustrated in the figures, because of the opening 112 in the lower pad layer 110, none of the metal, e.g., copper, of the lower pad layer 110 is present in the wire bond region 128. As a result, where probing or wire bonding in the region 128 may damage the upper pad layer 120, there is no copper in the bonding region 128 that could be exposed to the atmosphere. As a result, oxidation of copper is eliminated, thus improving the reliability of the device.

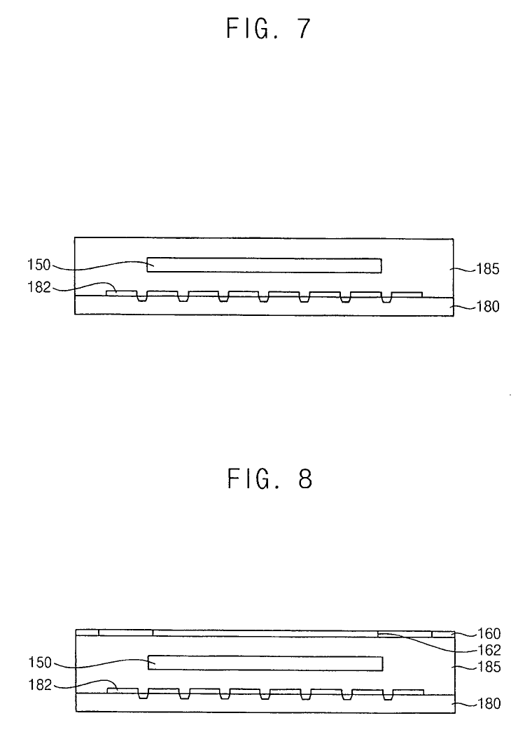

FIGS. 7 thorough 12 are schematic cross-sectional views illustrating an embodiment of a process of manufacturing the bonding pad structure 100 of a semiconductor device illustrated in FIG. 2. Referring to FIG. 7, device structures 182 are formed in the substrate 180. The ILD layer 185 is formed on the substrate 180, and the probing protect layer 150 may be formed in the ILD layer 185. The probing protect layer 150 can be formed of a metal or dielectric material. The probing protect layer prevents damage to the devices 182, which may be caused by cracking of layers under the pressure of probing or bonding. The probing protect layer 150 is an optional element.

Referring to FIG. 8, the first IMD layer 160 is formed on the ILD layer 185. The IMD layer 160 includes a trench 162 which is formed near the perimeter of the IMD layer 160 in the bonding pad structure. The trench 162 is used to form the conductive portion of the lower pad layer 110 which fills in the trench 162.

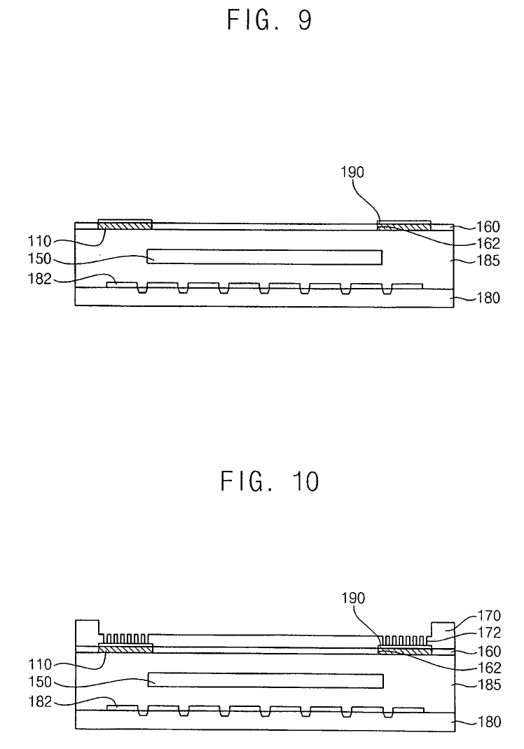

Referring to FIG. 9, the lower pad layer 110 is formed in the trench 162 by a process such as a single damascene process. A barrier metal layer 190 is optionally formed over the lower pad layer 110 to prevent migration of metal of the lower pad layer 110 during subsequent processing steps. The barrier metal layer 190 can be formed of, for example, Ta, TaN, TiN, WN.

Referring to FIG. 10, the second IMD layer 170 is formed over the lower pad layer 110. The second IMD layer 170 is shaped and patterned, such as by photolithographic masking and etching, to form the main opening for the body of the upper pad 120, as well as a plurality of via holes 172 arranged in a two-dimensional array or matrix to be aligned with and electrically coupled to the conductive portion of the lower pad layer 110.

Referring to FIG. 11, the patterned opening and via holes 172 in the second IMD layer 170 are filled with a conductive material such as aluminum or copper to form the upper pad layer 120. In the case where the upper pad layer 120 is formed of copper, an optional Ni/Pd/Au plating layer 121 may be formed on the upper pad layer 120.

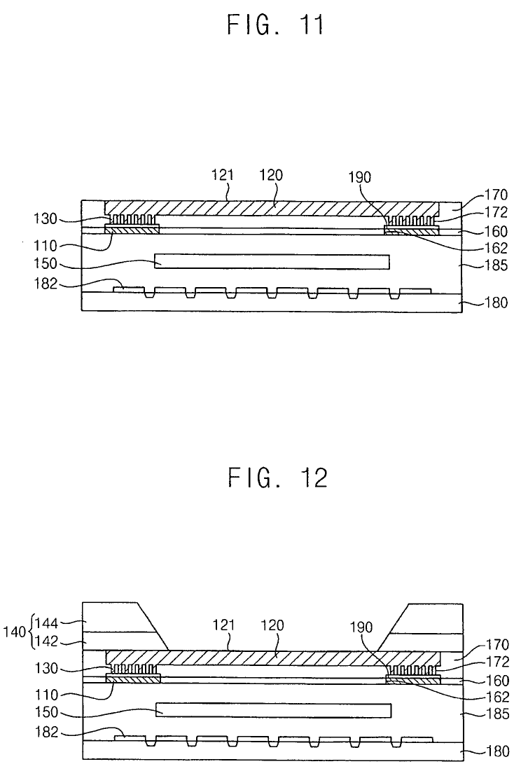

Referring to FIG. 12, the passivation layer 140 is formed over the upper pad layer 120 (and the optional Ni/Pd/Au plating layer 121) and the second IMD layer 170. The passivation layer 140 can include a silicon nitride layer 144 over a silicon oxide layer 142. Although not shown in FIG. 12, the polyimide layer 146 (see FIG. 2) can be formed over the passivation layer 140.

FIG. 13 is a schematic cross-sectional view of a bonding pad structure 100a of a semiconductor device in accordance with another embodiment of the invention. The embodiment of FIG. 13 differs from the embodiment of FIG. 2 in that the upper pad layer 120a of the embodiment of FIG. 13 has a contact plug region 130a which is different from the contact plug region 130 of the embodiment of FIG. 2. The upper pad layer 120a can be formed of, for example, copper or aluminum.

Description of elements of the embodiment of FIG. 13 that are the same as those of the embodiment of FIG. 2 will not be repeated.

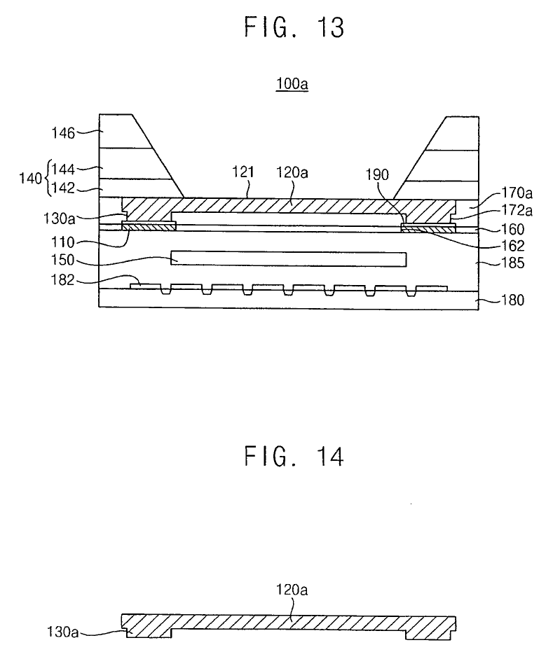

FIG. 14 contains a schematic cross-sectional view of the upper pad layer 120a of the bonding pad structure 100a of FIG. 13. Referring to FIGS. 13 and 14, the contact plug region 130a is a continuous conductive region instead of the two-dimensional array of conductive pins or plugs in the contact plug region 130 of the embodiment of FIG. 2. The continuous conductive contact plug region 130a is electrically coupled to the lower pad layer 110. The barrier metal layer 190 is optionally interposed between the upper pad layer 120a and the lower pad layer 110. In the case in which the barrier metal layer 190 is not present, the continuous conductive contact plug region 130a is in direct contact with the lower pad layer 110.

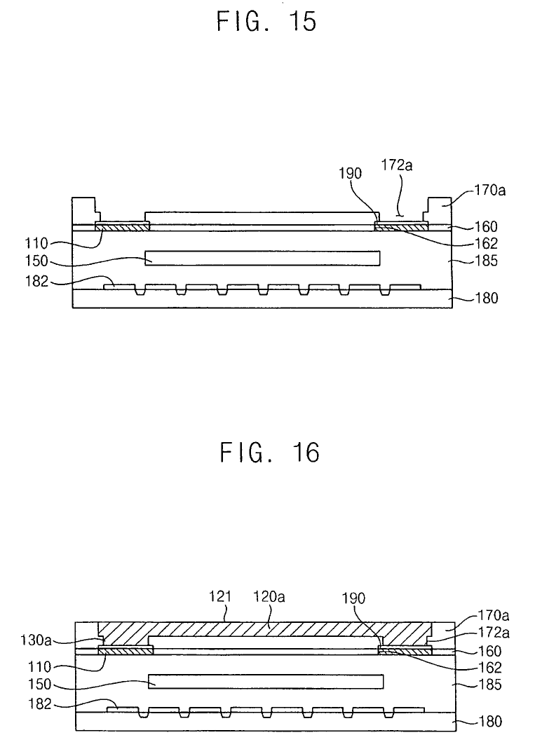

FIGS. 15 and 16 are schematic cross-sectional views illustrating the steps in fabricating the bonding pad structure 100a that are different from the steps in fabricating the bonding pad structure 100. Referring to FIG. 15, the second IMD layer 170a is formed over the lower pad layer 110. The second IMD layer 170a is shaped and patterned, such as by photolithographic masking and etching, to form the main opening for the body of the upper pad layer 120a, as well as the opening 172a for the contact plug region 130a of the upper pad layer 120a. It should be noted that the opening 172a is a continuous opening and not the plurality of via holes 172 in the embodiment of FIG. 2.

Referring to FIG. 16, the patterned main opening and opening 172a in the second IMD layer 170a are filled with the conductive material for the upper pad layer 120a to form the upper pad layer 120a.

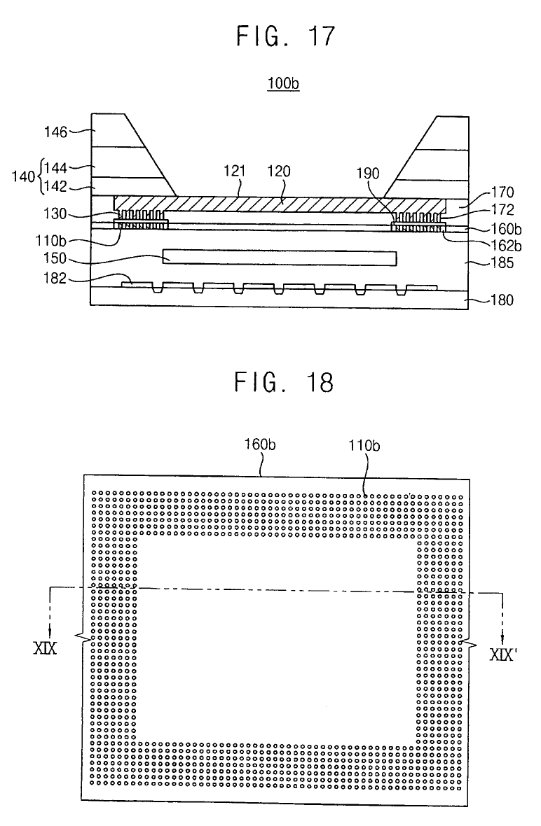

FIG. 17 is a schematic cross-sectional view of a bonding pad structure 100b of a semiconductor device in accordance with another embodiment of the invention. The embodiment of FIG. 17 differs from the embodiment of FIG. 2 in that the lower pad layer 110b of the embodiment of FIG. 17 has a different configuration than the lower pad layer 110 of the embodiment of FIG. 2. Specifically, the lower pad layer 110b of the embodiment of FIG. 17 is configured as a two-dimensional array or matrix of conductive pins or plugs, in contrast with the continuous conductive region of the lower pad layer 110 of the embodiment of FIG. 2. The first metal layer or lower pad layer 110 can be formed of, for example, copper or aluminum. The barrier metal layer 190 is optional and may not be used.

Description of elements of the embodiment of FIG. 17 that are the same as those of the embodiments of FIGS. 2 and/or 13 will not be repeated.

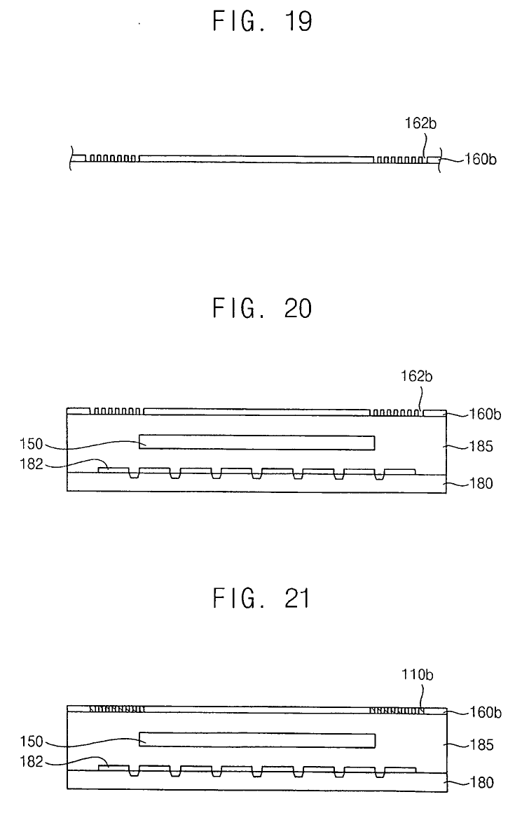

FIG. 18 contains a schematic top plan view of the lower pad layer 110b of the bonding pad structure 100b of FIG. 17, and FIG. 19 contains a schematic cross-sectional view of the lower pad layer 110b taken along line XIX-XIX′ of FIG. 18. Referring to FIGS. 17 through 19, the lower pad layer 110b includes a plurality of conductive pins or plugs arranged in a two-dimensional array or matrix and formed in the first IMD layer 160b. The conductive pins are electrically coupled to the array of conductive plugs in the contact plug region 130 of the upper pad layer 120. The barrier metal layer 190 is optionally interposed between the upper pad layer 130 and the lower pad layer 110b. However, where the barrier metal layer 190 is not used, the contact plug region 130 is in direct contact with the lower pad layer 110b. It should be noted that although the lower pad layer 110b is shown with the upper pad layer 130 of the embodiment of FIG. 2, it can also be used with the upper pad layer 130b of the embodiment of FIG. 13.

FIGS. 20 and 21 are schematic cross-sectional views illustrating the steps in fabricating the bonding pad structure 100b that are different from the steps in fabricating the bonding pad structures 100 and/or 100a. Referring to FIG. 20, the first IMD layer 160b is formed over the ILD layer 185. The first IMD layer 160b is shaped and patterned, such as by photolithographic masking and etching, to form the region where the lower pad layer 110b will be formed. Specifically, the first IMD layer 160b is patterned to have a plurality of vias 162b arranged in a two-dimensional array or matrix such that, when they are filled with the metal of the lower pad layer 110b, the lower pad layer 110b having the two-dimensional array of conductive pins or plugs is formed. Referring to FIG. 21, the metal of the lower pad layer 110b is formed in the vias of the first IMD layer 160b to create the lower pad layer 160b having the two-dimensional array of conductive pins, plugs or dots.

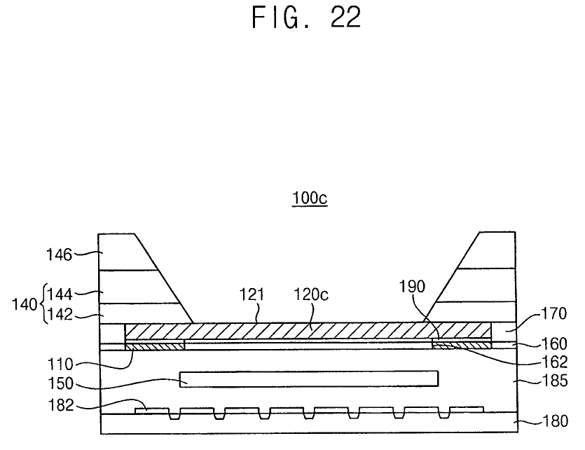

FIG. 22 is a schematic cross-sectional view of a bonding pad structure 100c of a semiconductor device in accordance with another embodiment of the invention. The embodiment of FIG. 22 differs from the embodiments of FIGS. 2, 13 and 17 in that the upper pad layer 120c does not include the contact plug region 130 of the previously described embodiments. Instead, the main body of the upper pad layer 120c is electrically coupled to the lower pad layer 110 without the intervening contact plug region 130. As noted above for the previously described embodiments, the barrier metal layer may be interposed between the upper pad layer 120c and the lower pad layer 110.

The embodiment of FIG. 22, in which the upper pad layer 120c does not have a contact plug region 130, is shown in connection with the bonding pad structure 100 described in connection with the embodiment of FIG. 2. It is noted that this is for illustration purposes only. The embodiment of the upper pad layer 120c without a contact plug region is applicable to all of the bonding pad structure embodiments described herein.

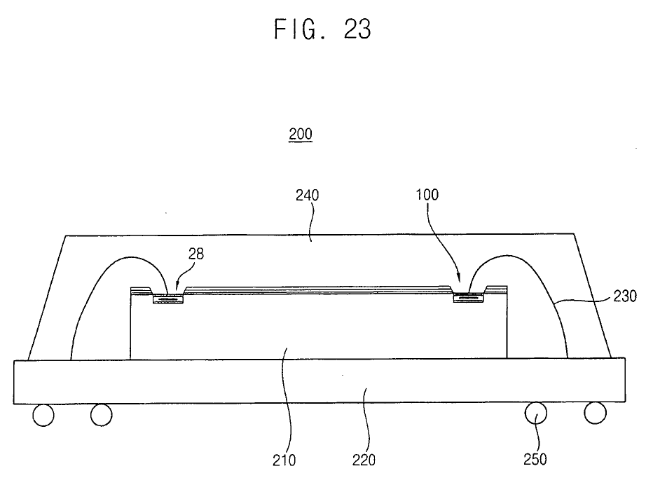

FIG. 23 contains a schematic cross-sectional view of a packaged semiconductor device 200 using the bonding pad structures of the invention. Referring to FIG. 23, a substrate 210, on which circuits and the bonding pad structures of the invention are formed, is mounted on the base 220 of the package. Bonding wires 230 connect the base 220 to the circuits in the substrate by attachment of the bonding wires through the bonding pad structures at the wire bond regions 28. The device is encapsulated in a protective package 240 made of a material such as epoxy. Conductive balls 250 connect the packaged device 200 to external circuits.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor device, comprising:
a bonding region at which bonding can be performed; and
a bonding pad structure in the bonding region and extending beyond the bonding region, the bonding pad structure comprising:
a first metal layer, and
a second metal layer over the first metal layer, wherein, in the first metal layer, metal is absent from the bonding region.

2. The semiconductor device of claim 1, wherein the first metal layer comprises copper.

3. The semiconductor device of claim 1, wherein the first metal layer comprises aluminum.

4. The semiconductor device of claim 1, further comprising a barrier metal layer between the first metal layer and the second metal layer.

5. The semiconductor device of claim 4, wherein the barrier metal layer comprises at least one of Ta, TaN, TiN and WN.

6. The semiconductor device of claim 1, wherein the second metal layer comprises aluminum.

7. The semiconductor device of claim 1, wherein the second metal layer comprises copper.

8. The semiconductor device of claim 7, further comprising a plating layer formed over the second metal layer.

9. The semiconductor device of claim 8, wherein the plating layer comprises at least one of nickel, lead and gold.

10. The semiconductor device of claim 1, wherein the first metal layer comprises a continuous conductive region electrically coupled to the second metal layer.

11. The semiconductor device of claim 1, wherein the first metal layer comprises a plurality of conductive pins electrically coupled to the second metal layer.

12. The semiconductor device of claim 1, wherein the second metal layer comprises a contact plug region electrically coupled to the first metal layer.

13. The semiconductor device of claim 12, wherein the contact plug region comprises a plurality of conductive plugs in contact with the first metal layer.

14. The semiconductor device of claim 12, wherein the contact plug region comprises a continuous conductive region electrically coupled to the first metal layer.

15. The semiconductor device of claim 1, further comprising a protection layer under the first metal layer.

16-30. (canceled)

31. A bonding pad structure, comprising:
a first metal layer, and
a second metal layer over the first metal layer, wherein, in the first metal layer, metal is absent from the bonding region.

32. The bonding pad structure of claim 31, wherein the first metal layer comprises copper.

33. The bonding pad structure of claim 31, wherein the first metal layer comprises aluminum.

34. The bonding pad structure of claim 31, further comprising a barrier metal layer between the first metal layer and the second metal layer.

35. The bonding pad structure of claim 34, wherein the barrier metal layer comprises at least one of Ta, TaN, TiN and WN.

36. The bonding pad structure of claim 31, wherein the second metal layer comprises aluminum.

37. The bonding pad structure of claim 31, wherein the second metal layer comprises copper.

38. The bonding pad structure of claim 37, further comprising a plating layer formed over the second metal layer.

39. The bonding pad structure of claim 38, wherein the plating layer comprises at least one of nickel, lead and gold.

40. The bonding pad structure of claim 31, wherein the first metal layer comprises a continuous conductive region electrically coupled to the second metal layer.

41. The bonding pad structure of claim 31, wherein the first metal layer comprises a plurality of conductive pins electrically coupled to the second metal layer.

42. The bonding pad structure of claim 31, wherein the second metal layer comprises a contact plug region electrically coupled to the first metal layer.

43. The bonding pad structure of claim 42, wherein the contact plug region comprises a plurality of conductive plugs electrically coupled to the first metal layer.

44. The bonding pad structure of claim 42, wherein the contact plug region comprises a continuous conductive region electrically coupled to the first metal layer.

45. The bonding pad structure of claim 31, further comprising a protection layer under the first metal layer.

46-60. (canceled)
